(19) United States
(12) Patent Application Publication
(10) Pub. No.: US 2026/0180520 A1
(43) Pub. Date: Jun. 25, 2026

(54) AMPLIFIER CIRCUIT

(71) Applicant: INDUSTRIAL TECHNOLOGY RESEARCH INSTITUTE, HSINCHU (TW)

(72) Inventors: Yun-Le LIN, Hsinchu City (TW); Wei-Zen CHEN, Hsinchu (TW); Wen-Shian SHIE, Hsinchu City (TW); Yungpin LEE, New Taipei City (TW)

(21) Appl. No.: 19/180,151

(22) Filed: Apr. 16, 2025

(30) Foreign Application Priority Data
Dec. 23, 2024 (TW) 113150275

(51) Int. Cl. H03F 3/08; H03F 3/45

(52) U.S. Cl. CPC H03F 3/087; H03F 3/45475

(57) ABSTRACT

An amplifier circuit is provided. The amplifier circuit comprises a first transconductance amplifier and a first transimpedance amplifier. The first transconductance amplifier receives a first input signal. A first input terminal of the first transimpedance amplifier is coupled to a first input terminal of the first transconductance amplifier. The first transimpedance amplifier comprises a first resistor and a first inverter. The first resistor is coupled between a first output terminal of the first transimpedance amplifier and the first input terminal of the first transimpedance amplifier. An output terminal of the first inverter is coupled to the first input terminal of the first transimpedance amplifier.

### CROSS-REFERENCE TO RELATED APPLICATION

This application claims priority to Taiwan Application Serial Number 113150275, filed Dec. 23, 2024, which is herein incorporated by reference in its entirety.

### BACKGROUND

### Field of Invention

The present disclosure relates to an amplifier circuit. More particularly, the present disclosure relates to an amplifier circuit having a feedback structure.

### Description of Related Art

A transimpedance amplifier (TIA) is a current to voltage converter. Specifically, the TIA converts an input current signal to an output voltage signal. A gain of the TIA is associated to a feedback structure of the TIA. The feedback structure of the TIA includes an active feedback structure using active elements and a passive feedback structure using passive elements. The active feedback structure helps increase a gain bandwidth product (GBP) of the TIA but the active feedback structure decrease a stability of the TIA. Compare to the active feedback structure, the passive feedback structure provides the better stability but the GBP of the TIA with the passive feedback structure is hard to increase because of a loading effect. To increase the GBP, large inductors are required, which causes area usage inefficiency.

### SUMMARY

In some embodiments, an amplifier circuit is provided. The amplifier circuit comprises a first transconductance amplifier and a first transimpedance amplifier. The first transconductance amplifier receives a first input signal. A first input terminal of the first transimpedance amplifier is coupled to a first input terminal of the first transconductance amplifier. The first transimpedance amplifier comprises a first resistor and a first inverter. The first resistor is coupled between a first output terminal of the first transimpedance amplifier and the first input terminal of the first transimpedance amplifier. An output terminal of the first inverter is coupled to the first input terminal of the first transimpedance amplifier.

In some embodiments, an amplifier circuit is provided. The amplifier circuit comprises a first transconductance amplifier and a first transimpedance amplifier. The first transconductance amplifier has a first input terminal and a second input terminal that are configured to receive a first input signal and a second input signal respectively. The first and second input signals are a differential signal pair. The first transconductance amplifier further comprises a first output terminal and a second output terminal that are configured to generate a first output signal and a second output signal corresponding to the first and second input signals respectively. The first transimpedance amplifier comprises a first inverter, a first resistor and a second inverter. An input terminal of the first inverter is coupled to the first output terminal of the first transconductance amplifier. The first resistor is coupled between the input terminal of the first inverter and an output terminal of the first inverter. An input terminal of the second inverter is coupled to the output terminal of the first inverter, and a output terminal of the second inverter is coupled to the second output terminal of the first transconductance amplifier.

### BRIEF DESCRIPTION OF THE DRAWINGS

The invention can be more fully understood by reading the following detailed description of the embodiment, with reference made to the accompanying drawings as follows:

FIG. 1 is a schematic diagram of a circuit in accordance with various embodiments of the present disclosure.

FIG. 2 is a schematic diagram of a circuit configured with respect to the circuit of FIG. 1 in accordance with various embodiments of the present disclosure.

FIG. 3 is a schematic diagram of a circuit configured with respect to the circuit of FIG. 2 in accordance with various embodiments of the present disclosure.

FIG. 4 is a circuit configured with respect to the circuit of FIG. 3, in accordance with various embodiments of the present disclosure.

FIG. 5 is a schematic diagram of a circuit configured with respect to the circuits of FIGS. 1-4, in accordance with various embodiments of the present disclosure.

FIG. 6 is a circuit configured with respect to the circuits 1 of FIGS. 1-5.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

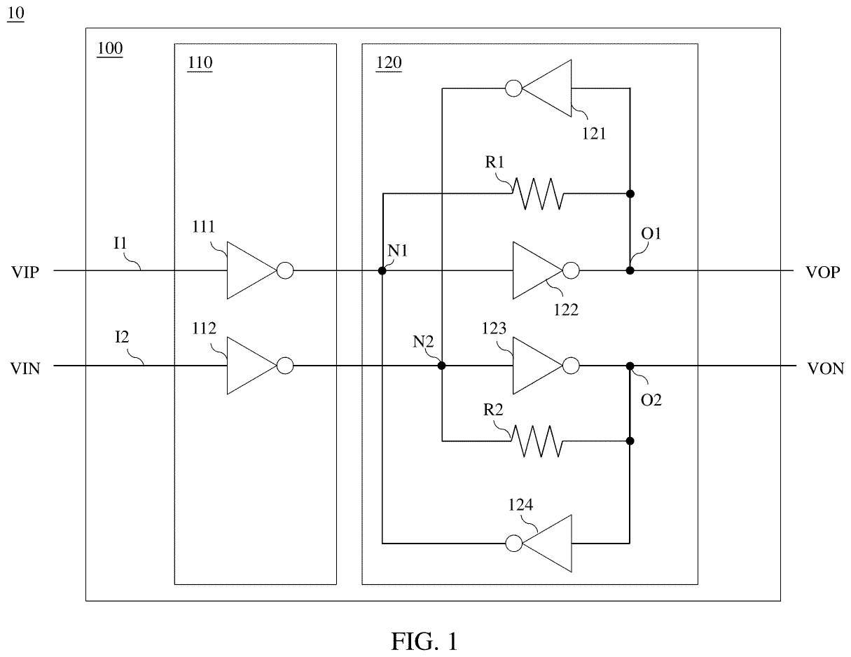

Reference is now made to FIG. 1. FIG. 1 is a schematic diagram of a circuit 10 in accordance with various embodiments of the present disclosure. In some embodiments, the circuit 10 is an integrated circuit (IC). In application, the circuit 10 is an amplifier circuit. In some embodiments, the circuit 10 is a differential amplifier circuit. In some embodiments, the circuit 10 is a differential voltage amplifier circuit.

As shown in FIG. 1, the circuit 10 has an input terminal I1 and an input terminal I2 configured to receive a voltage signal VIP and a voltage signal VIN respectively. In some embodiments, the signal VIP and the signal VOP are a differential signal pair. In some embodiments, the input terminal I1 is a positive terminal of the circuit 10 being an amplifier and the input terminal I2 is a negative terminal of the circuit 10 being the amplifier.

The circuit 10 has an output terminal O1 and an output terminal O2 configured to output an voltage signal VOP and a voltage signal VON respectively. In some embodiments, the circuit 10 amplifies the voltage signal VIP and the voltage signal VIN respectively to generate the voltage signals VOP and VON which are a differential signal pair.

In some embodiments, the output terminal O1 is configured as a positive output terminal of the circuit 10 being the amplifier. The output terminal O2 is configured as a negative output terminal of the circuit 10 being the amplifier.

In some embodiments, the circuit 10 includes at least a stage of amplifier circuit 100. As shown in FIG. 1, a stage of the amplifier circuit 100 includes a transconductance amplifier (TCA) circuit 110 and a transimpedance amplifier (TIA) circuit 120. The TCA circuit 110 is coupled between the input terminals I1-I2 and the TIA circuit 120. The TIA circuit 120 is coupled between the output terminals O1-O2 and the TCA circuit 110.

In some embodiments, the TCA circuit 110 is configured to generate a current signal according to the inputted voltage signals VIP and VIN. The TCA circuit 110 is a device converting an inputted voltage signal to an outputted current signal, in which a gain of the TCA circuit 110 is defined as a ratio of a source current to the inputted voltage.

The TIA circuit 120 is configured to receive the current signal generated by the TCA circuit 110 and generate the outputted voltage signals VOP and VON according to the current signal. The TIA circuit 120 is a circuit converting a current signal to a voltage signal, in which a gain of the TIA circuit 120 is associated to the feedback structure thereof. In some embodiments, utilizing only active feedback structure of active elements in the TIA circuit 120 helps increase a gain bandwidth product (GBP) of the TIA circuit 120 but it is not beneficial to a stability of the TIA circuit 120. In some embodiments, utilizing only passive feedback structure of passive elements in the TIA circuit 120 provides a better stability but it is hard to improve the GBP. Larger inductor is needed, and therefore the area efficiency is reduced.

In some embodiments, the TIA circuit 120 of the amplifier circuit 100 combines advantages of the active feedback structure and the passive feedback structure, and a balance between the gain, the bandwidth and the stability is met to suit different applications. Details about the active and passive feedback structure are further described in the following paragraphs.

In some embodiments, the gain of the amplifier circuit 100 is equal to a multiplication between the gain of the TCA circuit 110 and the gain of the TIA circuit 120.

In some embodiments, the TCA circuit 110 includes an inverter 111 and an inverter 112. The TCA circuit 110 configured to generate current signals according to the inputted voltage signals VIP and VIN separately. The input terminal and the output terminal of the inverter 111 are coupled to the input terminals I1 and a node N1 respectively. The input terminal and the output terminal of the inverter 112 are coupled to the input terminal I2 and a node N2. The inverter 111 outputs a current to amplify a voltage of the node N1 and make the voltage of the node N1 inverted to the voltage signal VIP. The inverter 112 outputs a current to amplify a voltage of the node N2 and make the voltage of the node N2 inverted to the voltage signal VIP.

In some embodiments, the TIA circuit 120 includes inverters 121-124 and resistors R1 and R2, in which the inverters 122 and the inverters 123 are configured as two amplifiers of the TIA circuit 120.

The inverter 121 is configured as an active feedback structure of the amplifier of the inverter 122. The resistor R1 is configured as a passive feedback structure of the amplifier of the inverter 122.

The inverter 124 is configured as an active feedback structure of the amplifier of the inverter 123. The resistor R2 is configured as a passive feedback structure of the amplifier of the inverter 123.

The input terminal and the output terminal of the inverter 122 are coupled to the node N1 and the output terminal O1 respectively. The input terminal and the output terminal of the inverter 123 are coupled to the node N2 and the output terminal O2 respectively. The input terminal and the output terminal of the inverter 121 are coupled to the output terminal O1 and the node N2 respectively. The input terminal and the output terminal of the inverter 124 are coupled to the output terminal O2 and the node N1.

The resistor R1 is coupled between the node N1 and the output terminal O1. The resistor R2 is coupled between the node N2 and the output terminal O2. The resistor R1 is configured to feedback the output signal of the inverter 122 to the input terminal of the inverter 122. The resistor R1 is a passive element implementing the passive feedback of signal of the inverter 122.

The inverter 124 is configured to feedback the output signal of the inverter 123 to the input terminal of the inverter 122. The inverter 124 is an active element implementing the active feedback.

Specifically, the resistor R1 and the inverter 124 are configured to feedback a positive signal to decrease voltage change at the node N1 and further keep the voltage at the output terminal O1 stable.

Similarly, the resistor R2 is configured to feedback the output signal of the inverter 123 to the input terminal of the inverter 123. The resistor R2 is a passive element implementing the passive feedback of signal of the inverter 123.

The inverter 121 is configured to feedback the output signal of the inverter 122 to the input terminal of the inverter 123. The inverter 121 is an active element implementing the active feedback.

Specifically, the resistor R2 and the inverter 121 are configured to feedback a negative signal to decrease voltage change at the node N2 and further keep the voltage at the output terminal O2 stable, e.g., keeping the voltage level of the voltage signal VON as −8V.

According to some embodiments, the gain of the TIA circuit 120 is according to the transconductances of the transistors in the inverters 121 and 124 and the resistances of the resistors R1 and R2.

According to above embodiments, the TIA circuit 120 includes two amplifiers (the inverter 122 and the inverter 123). Each amplifier is configured to have an active feedback structure and a passive feedback structure to stabilize output signals of the two amplifiers. As a result, the TIA circuit 120 of the amplifier circuit 100 combines advantages of the active and passive feedback structures to meet the balance between the gain, bandwidth and stability to suit different applications.

In some embodiments, the circuit 10 has a symmetric structure. Specifically, the inverters 111 and 112 have similar configurations. The inverters 122 and 123 have similar configurations. The inverters 121 and 124 have similar configurations. The resistors R1 and R2 have similar configurations. For example, the inverters 111 and 112 have a same gain. The inverters 122 and 123 have a same gain. The inverters 121 and 124 have a same gain. The resistors R1 and R2 have a same resistance.

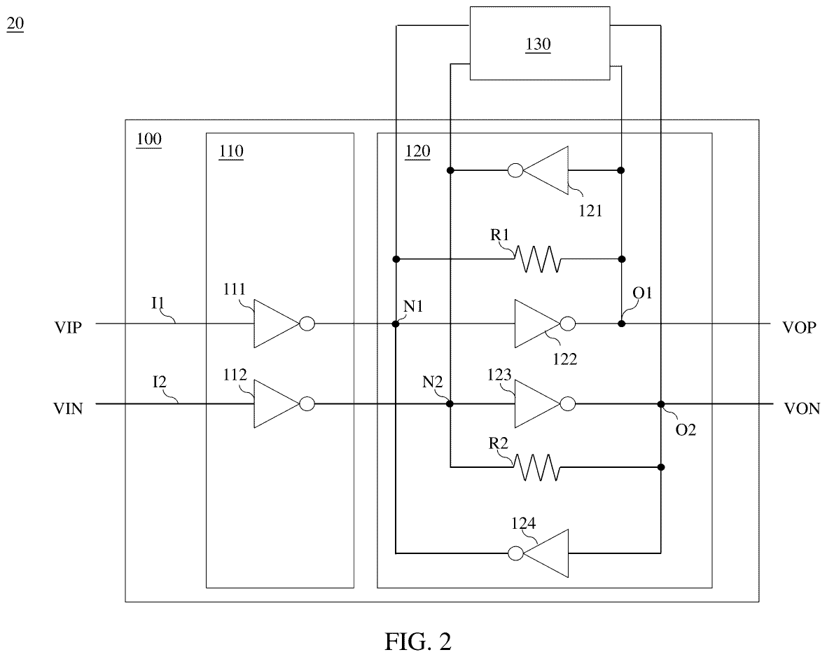

Reference is now made to FIG. 2. FIG. 2 is a schematic diagram of a circuit 20 configured with respect to the circuit 10 of FIG. 1 in accordance with various embodiments of the present disclosure. With respect to the embodiments of FIG. 1, like elements in FIG. 2 are designated with the same reference numbers for ease of understanding. The specific operations of similar elements, which are already discussed in detail in above paragraphs, are omitted herein for the sake of brevity.

The difference between the circuit 10 in FIG. 1 and the circuit 20 in FIG. 2 is that the circuit 20 further includes a circuit 130. As shown in FIG. 2, the circuit 130 is configured to feedback the signals at the output terminals O1-O2 to the nodes N1-N2 to adjust the voltages at the nodes N1-N2. In some embodiments, the circuit 130 adjusts the voltage signals VOP and VON through the feedback to reduce a common mode noise and/or a differential mode noise.

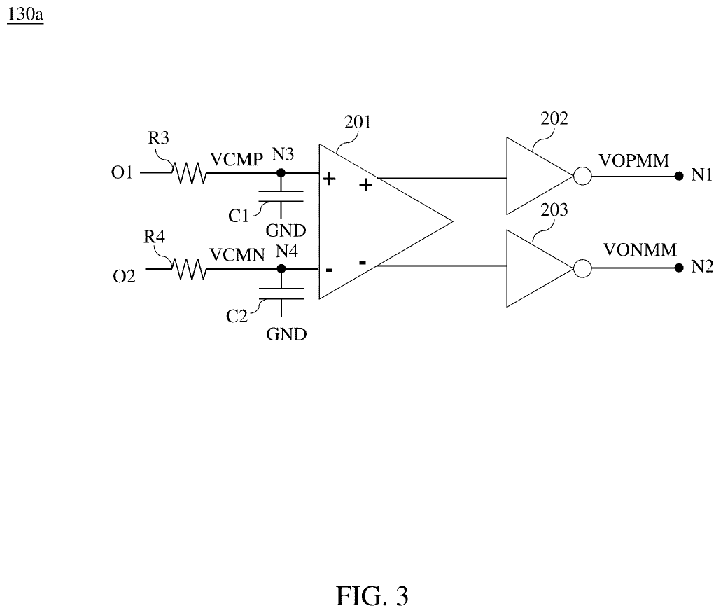

Reference is now made to FIG. 3. FIG. 3 is a schematic diagram of a circuit 130a configured with respect to the circuit 130 of FIG. 2 in accordance with various embodiments of the present disclosure. With respect to the embodiments of FIGS. 1-2, like elements in FIG. 3 are designated with the same reference numbers for ease of understanding.

As shown in FIG. 3, the circuit 130a is a differential mode feedback circuit sampling the voltages at the output terminals O1 and O2, and amplifying and feedback the sampled voltages to the nodes N1 and N2 to reduce the differential mode noise of the voltage signals VOP and VON. The circuit 130a includes a resistor R3, a resistor R4, a capacitor C1, a capacitor C2, an amplifier 201, an inverter 202 and an inverter 203.

In some embodiments, the amplifier 201 is an operational amplifier (OP). In some embodiments, the amplifier 201 is a fully differential amplifier.

For illustration, the resistor R3 is coupled between the output terminal O1 and a node N3. The capacitor C1 is coupled between the node N3 and a ground GND. The resistor R4 is coupled between the output terminal O2 and a node N4. The capacitor C2 is coupled between the node N4 and the ground GND.

The node N3 is coupled to the positive input terminal of the amplifier 201. The node N4 is coupled to the negative input terminal of the amplifier 201.

The positive output terminal of the amplifier 201 is coupled to the input terminal of the inverter 202. The negative output terminal of the amplifier 201 is coupled to the input terminal of the inverter 203.

The output terminal of the inverter 202 is coupled to the node N1 and the output terminal of the inverter 203 is coupled to the node N2.

In some embodiments, the resistors R3 and R4 have similar configurations. The capacitors C1 and C2 have similar configurations. The inverters 202 and 203 have similar configurations. For example, the resistors R3 and R4 have a same resistance. The capacitors C1 and C2 have a same capacitance. The inverters 202 and 203 include similar elements.

In operation, the resistors R3 and the capacitor C1 form a filter circuit for filtering the voltage signal VOP at the output terminal O1 to generate a voltage signal VCMP that corresponds to an average value of the voltage signal VOP. Similarly, the resistor R4 and the capacitor C2 form a filter circuit for filtering the voltage signal VON at the output terminal O2 to generate a voltage signal VCMN that corresponds to an average value of the voltage signal VON.

The amplifier 201 detects a voltage difference between the voltage signal VCMP and the voltage signal VCMN and generates a differential signal pair at the positive and negative output terminals of the amplifier 201 according to the voltage difference. The inverters 202 and 203 generate a output differential signal pair (the voltage signals VOPMM and VONMM) inverted to the differential signal pair by the amplifier 201.

The voltage signals VOPMM and VONMM are outputted to the nodes N1 and N2 as differential compensation signals of the circuit 10.

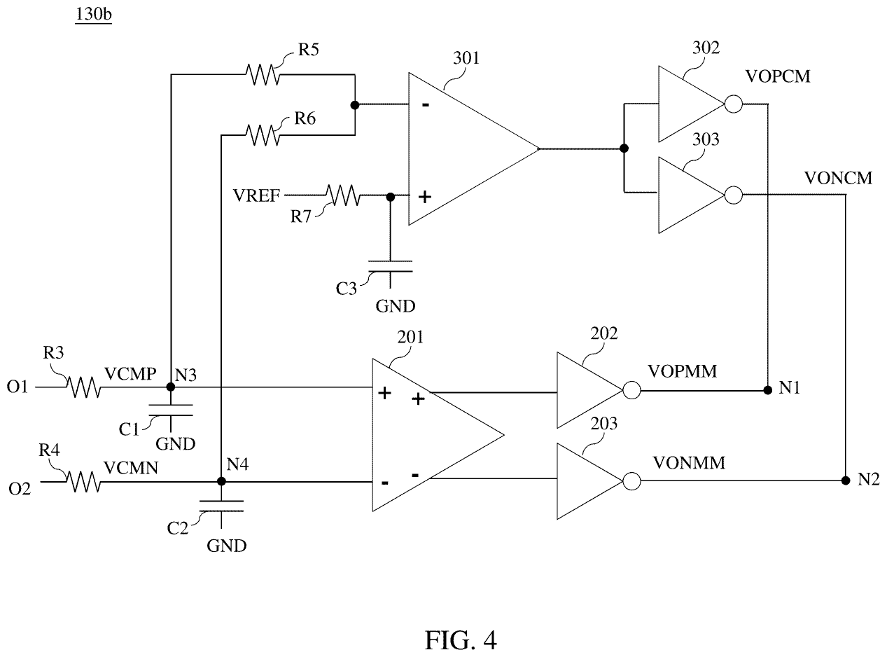

Reference is now made to FIG. 4. FIG. 4 is a circuit 130b configured with respect to the circuit 130a of FIG. 3, in accordance with various embodiments of the present disclosure. With respect to the embodiments of FIGS. 1-3, like elements in FIG. 4 are designated with the same reference numbers for ease of understanding.

Compared with the circuit 130a in FIG. 3, the circuit 130b in FIG. 4 also includes the elements (the resistors R3-R4, the capacitors C1-C2, the amplifier 201 and the inverters 202-203) forming the differential mode feedback circuit. Compared with the circuit 130a in FIG. 3, the circuit 130b further includes resistors R5-R7, a capacitor C3, an amplifier 301 and inverters 302-303 that are configured to form a common mode feedback circuit. The circuit 130b samples the voltages at the output terminals O1-O2. The circuit 130b amplifies and feedback the sampled voltages to the nodes N1 and N2 to reduce the common mode noise of the voltage signals VOP and VON.

For illustration, the resistor R5 is coupled between the node N3 and the negative output terminal of the amplifier 301. The resistor R6 is coupled between the node N4 and the negative output terminal of the amplifier 301.

The resistor R7 is coupled between the reference voltage VREF and the positive output terminal of the amplifier 301.

The capacitor C3 is coupled between the positive input terminal of the amplifier 301 and the ground GND.

The output terminal of the amplifier 301 is coupled to the input terminals of the inverters 302 and 303.

The output terminal of the inverter 302 is coupled to the node N1 and the output terminal of the inverter 303 is coupled to the node N2.

In some embodiments, the resistors R5 and R6 have similar configurations. The inverters 302 and 303 have similar configurations. For example, the resistors R5 and R6 have a same resistance. The inverters 302 and 303 include similar elements.

According to some embodiments, the resistor R5 and R6 receive the voltage signals VCMP and VCMN respectively and are configured to generate a voltage signal corresponding to an average value of the voltage signals VCMP and VCMN at the negative input terminal of the amplifier 301.

The resistor R7 and the capacitor C3 form a filter circuit for filtering the reference voltage VREF and generate a filtered signal at the positive inpit terminal of the amplifier 301.

In some embodiments, the amplifier 301 is a single ended output operational amplifier. In some embodiments, the amplifier 301 generates the voltage signal at the output terminal according to the voltage value at the positive input terminal minus the voltage value at the negative input terminal.

The inverters 302, 303 receive the voltage signal outputted by the amplifier 301 and generate voltages signal VOPCM and VONCM inverted to the voltage signal by the amplifier 301 to the nodes N1 and N2 as a common mode compensation signal to the circuit 10. According to some embodiments, the voltage signals VOPCM and VONCM have a same voltage value.

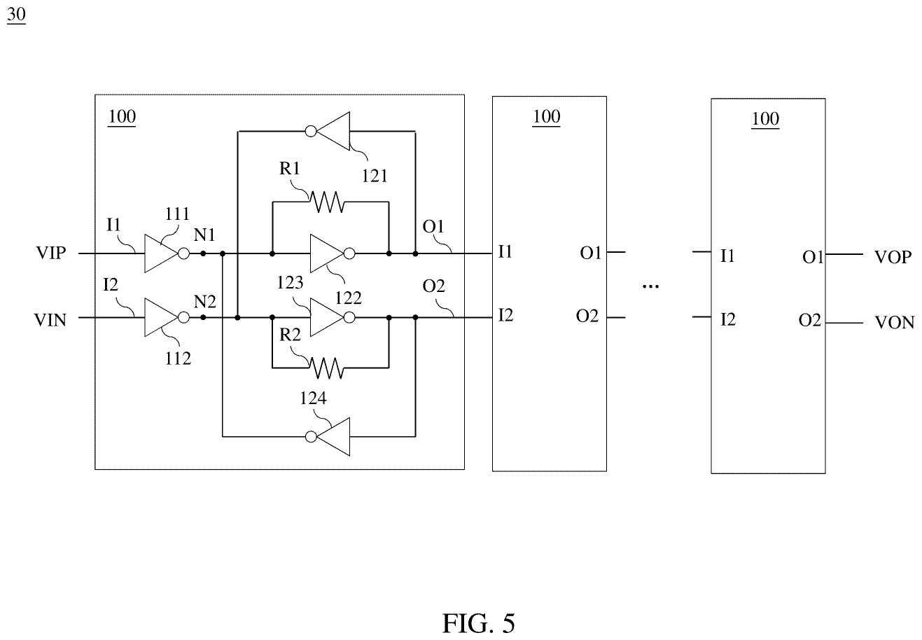

Reference is now made to FIGS. 1-5. FIG. 5 is a schematic diagram of a circuit 30 configured with respect to the circuits 10 and 20 of FIGS. 1-4, in accordance with various embodiments of the present disclosure. With respect to the embodiments of FIGS. 1-4, like elements in FIG. 5 are designated with the same reference numbers for ease of understanding.

Compared with the circuits 10 and 20 of FIGS. 1-4, the circuit 30 of FIG. 5 includes multiple amplifier circuits 100. These amplifier circuits 100 form a multi-stage amplifier circuit. In some embodiments, a gain of the circuit 30 is equal to the product of gains of these amplifier circuits 100. For simplicity, the elements of the amplifier circuit 100 in the stages aside from the first stages are omitted in FIG. 5.

As shown in FIG. 5, the amplifier circuits 100 of the circuit 30 are coupled in series. Specifically, the input terminals I1 and I2 of the amplifier circuit 100 in the first stage receive the voltage signals VIP and VIN.

The input terminals I1 and I2 of the amplifier circuit 100 in the second stage are coupled to the output terminals O1 and O2 of the amplifier circuit 100 in the first stage respectively. The output terminals O1 and O2 of the amplifier circuit 100 in the second stage are coupled to the input terminals I1 and I2 of the amplifier circuit 100 in the third stage. The amplifier circuits 100 in the following stages are coupled in a similar manner.

The output terminals O1 and O2 of the amplifier circuits 100 generate the voltage signal VOP and VON respectively.

In some embodiments, the circuit 30 further includes the circuit 130a or the circuit 130 b as shown in FIGS. 3 and 4. In the circuit 130a or the circuit 130b of the circuit 30, the resistors R3 and R4 are coupled to the output terminals O1 and O2 of the amplifier circuit 100 in the last stage, and the output terminals of the inverters 202 and 203 are coupled to the nodes N1 and N2 of the amplifier circuit 100 in the first stage respectively. In the circuit 103b of the circuit 30, the output terminals of the inverters 302 and 303 are coupled to the nodes N1 and N2 of the amplifier circuit 100 in the first stage respectively.

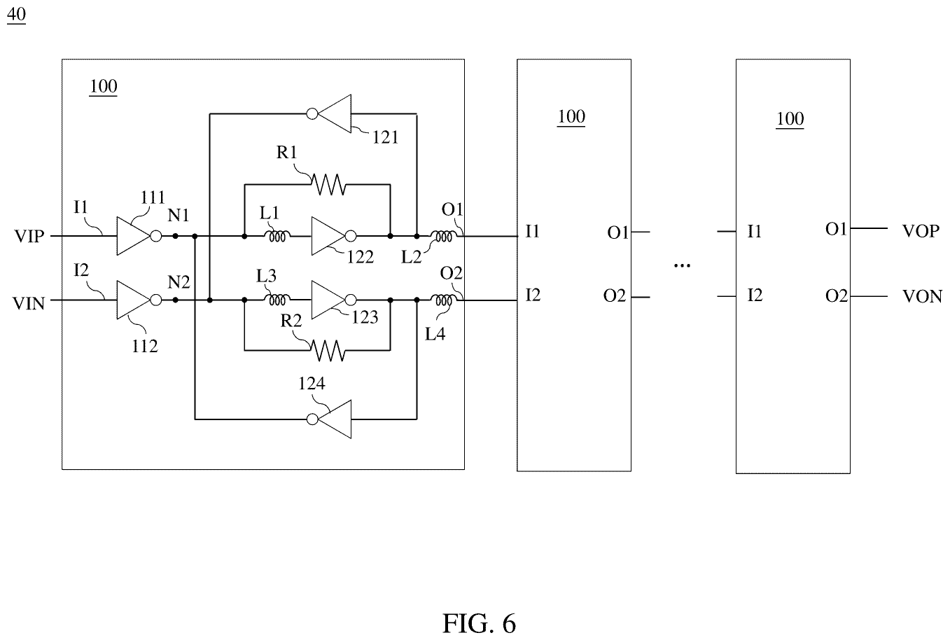

Reference is now made to FIGS. 1-6. FIG. 6 is a circuit 40 configured with respect to the circuits 10, 20 and 30 of FIGS. 1-5. With respect to the embodiments of FIGS. 1-5, like elements in FIG. 6 are designated with the same reference numbers for ease of understanding.

As shown in FIG. 6, compared with the amplifier circuits 100 in the circuits 10, 20 and 30, the amplifier circuit 100 in the circuit 40 further includes inductors L1-L4.

For illustration, the inductor L1 is coupled between the node N1 and the inverter 122. The inductor L2 is coupled between the output terminal of the inverter 122 and the output terminal O1. The inductor L3 is coupled between the node N2 and the inverter 123. The inductor L4 is coupled between the output terminal of the inverter 123 and the output terminal O2. For simplicity, elements of the amplifier circuit 100 in the stages aside from the first stage are omitted in FIG. 6.

In operation, the inductors L1-L4 are used to increase the bandwidth of the amplifier circuit 100 to further increase the bandwidth of the circuit 40.

In some embodiments, the inductors L1 and L3 have similar configurations. The inductors L2 and L4 have similar configurations. For example, the inductors L1 and L3 have a same inductance, and the inductors L2 and L4 have a same inductance.

The configurations of FIGS. 1-6 are given for illustrative purposes. Various implements are within the contemplated scope of the present disclosure. For example, in some embodiments, each of the circuits 30 and 40 has two stages of the amplifier circuit 100.

In view of the above, a hybrid feedback amplifier circuit is provided. The hybrid feedback amplifier circuit includes an active feedback structure and a passive feedback structure. The hybrid feedback amplifier circuit combines advantages of the active and passive feedback structures to optimize the GBP and the stability thereof.

What is claimed is:

1. An amplifier circuit, comprising:
a first transconductance amplifier configured to receive a first input signal; and
a first transimpedance amplifier, wherein a first input terminal of the first transimpedance amplifier is coupled to a first input terminal of the first transconductance amplifier,
wherein the first transimpedance amplifier comprises:
a first resistor coupled between a first output terminal of the first transimpedance amplifier and the first input terminal of the first transimpedance amplifier; and
a first inverter, wherein an output terminal of the first inverter is coupled to the first input terminal of the first transimpedance amplifier.

2. The amplifier circuit of claim 1, wherein the first transconductance amplifier comprises:
a second inverter, wherein an input terminal of the second inverter is configured to receive the first input signal, and an output terminal of the second inverter is coupled to the first output terminal of the first transconductance amplifier.

3. The amplifier circuit of claim 2, wherein the first transconductance amplifier further comprises:
a third inverter, wherein an input terminal of the third inverter is configured to receive a second input signal, and an input terminal of the third inverter is coupled to a second output terminal of the first transconductance amplifier.

4. The amplifier circuit of claim 3, wherein the first input signal is inverted to the second input signal.

5. The amplifier circuit of claim 1, wherein the first transimpedance amplifier further comprises:
a second inverter, wherein an input terminal of the second inverter is coupled to the first input terminal of the first transimpedance amplifier, and an output terminal of the second inverter is coupled to the first output terminal of the first transimpedance amplifier.

6. The amplifier circuit of claim 5, wherein the first transimpedance amplifier further comprises:
a third inverter, wherein an input terminal of the third inverter is coupled to a second input terminal of the first transimpedance amplifier, and an output terminal of the third inverter is coupled to a second output terminal of the first transimpedance amplifier,
wherein the second inverter and the third inverter are configured to generate a first output signal and a second output signal respectively,
wherein the first output signal is inverted to the second output signal.

7. The amplifier circuit of claim 6, wherein the first transimpedance amplifier further comprises:
a second resistor coupled between the second output terminal of the first transimpedance amplifier and the second input terminal of the first transimpedance amplifier; and
a fourth inverter, wherein an input terminal of the fourth inverter is coupled to first output terminal of the first transimpedance amplifier, and an output terminal of the fourth inverter is coupled to second input terminal of the first transimpedance amplifier.

8. The amplifier circuit of claim 7, wherein a resistance of the first resistor is equal to a resistance of the second resistor.

9. The amplifier circuit of claim 6, further comprises:
a differential mode feedback circuit comprising:
a differential amplifier configured to generate a third output signal and a fourth output signal according to the first and second output signals;
a fourth inverter, wherein an input terminal of the fourth inverter is coupled to the third output signal, and an output terminal of fourth inverter is coupled to the first input terminal of the first transimpedance amplifier; and
a fifth inverter, wherein an input terminal of the fifth inverter is coupled to the fourth output signal, wherein an output terminal of the fifth inverter is coupled to the second input terminal of first transimpedance amplifier.

10. The amplifier circuit of claim 9, further comprising:
a common mode feedback circuit comprising:
an amplifier configured to generate a fifth output signal according to the first output signal, the second output signal and a reference voltage;
a sixth inverter, wherein an input terminal of the sixth inverter is coupled to the fifth output signal, and an output terminal of the sixth inverter is coupled to the first input terminal of the first transimpedance amplifier; and
a seventh inverter, an input terminal of the seventh inverter is coupled to the fifth output signal, wherein an output terminal of the seventh inverter is coupled the second input terminal of the first transimpedance amplifier.

11. The amplifier circuit of claim 1, further comprising:
a second transconductance amplifier, wherein a first input terminal of the second transconductance amplifier is coupled to the first output terminal to the first transimpedance amplifier; and
a second transimpedance amplifier, wherein a first input terminal of the second transimpedance amplifier is coupled to a first output terminal of the second transconductance amplifier,
wherein the second transimpedance amplifier comprising:
a second resistor coupled between a first output terminal of the second transimpedance amplifier and the first input terminal of the second transimpedance amplifier; and
a second inverter, wherein an output terminal of the second inverter is coupled to the first input terminal of the second transimpedance amplifier.

12. The amplifier circuit of claim 11, further comprising:
a first inductor coupled between the first output terminal of the first transconductance amplifier and the first input terminal of the first transimpedance amplifier; and
a second inductor coupled between the first output terminal of the first transimpedance amplifier and the first input terminal of the second transconductance amplifier.

13. An amplifier circuit comprising:
a first transconductance amplifier having a first input terminal and a second input terminal that are configured to receive a first input signal and a second input signal respectively, wherein the first and second input signals are a differential signal pair,
wherein the first transconductance amplifier further comprises a first output terminal and a second output terminal that are configured to generate a first output signal and a second output signal corresponding to the first and second input signals respectively; and
a first transimpedance amplifier comprising:
a first inverter, wherein an input terminal of the first inverter is coupled to the first output terminal of the first transconductance amplifier;
a first resistor coupled between the input terminal of the first inverter and an output terminal of the first inverter; and
a second inverter, wherein an input terminal of the second inverter is coupled to the output terminal of the first inverter, and a output terminal of the second inverter is coupled to the second output terminal of the first transconductance amplifier.

14. The amplifier circuit of claim 13, wherein the first transimpedance amplifier further comprises:
a third inverter, wherein an input terminal of the third inverter is coupled to the second output terminal of the first transconductance amplifier;
a second resistor coupled between the input terminal of the third inverter and an output terminal of the third inverter; and
a fourth inverter, wherein an input terminal of the fourth inverter is coupled to the output terminal of the third inverter, and an output terminal of the fourth inverter is coupled to the first output terminal of the first transconductance amplifier.

15. The amplifier circuit of claim 14, further comprising:
a first inductor coupled between the first output terminal of the first transconductance amplifier and the input terminal of the first inverter; and
a second inductor coupled between the second output terminal of the first transconductance amplifier and the input terminal of the third inverter.

16. The amplifier circuit of claim 14, further comprising:
a second transconductance amplifier, wherein a first input terminal and a second input terminal of the second transconductance amplifier are coupled to the output terminal of the first inverter and the output terminal of the third inverter.

17. The amplifier circuit of claim 16, further comprising:
a second transimpedance amplifier comprising:
a fifth inverter, wherein an input terminal of the fifth inverter is coupled to a first output terminal of the second transconductance amplifier;
a third resistor coupled between the input terminal of the fifth inverter and an output terminal of the fifth inverter; and
a sixth inverter, wherein an input terminal of the sixth inverter is coupled to the output terminal of the fifth inverter, and an output terminal of the sixth inverter is coupled to a second output terminal of the second transconductance amplifier.

18. The amplifier circuit of claim 16, further comprising:
a first inductor coupled between the output terminal of the first inverter and the first output terminal of the second transconductance amplifier; and
a second inductor coupled between the output terminal of the third inverter and the second output terminal of the second transconductance amplifier.

19. The amplifier circuit of claim 18, wherein an inductance of the first inductor is equal to an inductance of the second inductor.

20. The amplifier circuit of claim 13, wherein the first transconductance amplifier comprises:
a third inverter coupled between the first input terminal of the first transconductance amplifier and the first output terminal of the first transconductance amplifier; and
a fourth amplifier coupled between the second input terminal of the first transconductance amplifier and the second output terminal of the first transconductance amplifier.
